(19) United States
(12) Patent Application Publication
(10) Pub. No.: US 2004/0126693 A1
(43) Pub. Date: Jul. 1, 2004

(54) Positive photosensitive composition and method of pattern formation using the same

(75) Inventors: Shih-Fan Wang, Taipei (TW); Shing-Tza Liou, Hsinchu (TW); Shih-Jung Tsai, Hsinchu (TW); Steve Lien-Chung Hsu, Tainan (TW); Po-I Lee, Kaohsiung (TW)

Correspondence Address: SUGHRUE MION, PLLC, 2100 PENNSYLVANIA AVENUE, N.W., SUITE 800, WASHINGTON, DC, 20037, US

(73) Assignee: INDUSTRIAL TECHNOLOGY RESEARCH INSTITUTE.

(21) Appl. No.: 10/624,487

(22) Filed: Jul. 23, 2003

(30) Foreign Application Priority Data
Nov. 21, 2002 (TW) 91133956

(51) Int. Cl. G03F 7/023; G03F 7/30

(52) U.S. Cl. 430/191; 430/192; 430/193; 430/165; 430/325; 430/330

(57) ABSTRACT

A positive photosensitive composition and method of pattern formation using the same. The composition comprises a precursor of poly(imide-benzoxazole) (PIBO) copolymer prepared by the reaction of trimellitic anhydride halide monomer with bis(o-diaminophenol) monomer; a photosensitizer; and a solvent. The PIBO copolymer is characterized by the following repeating unit:

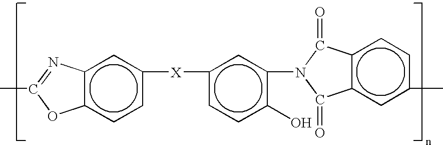

wherein X is —O—, —S—, —C(CF₃)₂—, —C(CH₃)₂—, —CO—, —CH₂—, —SO₂—, —SO—, or a bond; and n is an integer.

### BACKGROUND OF THE INVENTION

1. Field of the Invention

The present invention relates to a positive photosensitive composition. More particularly, the present invention relates to a positive photosensitive composition comprising a precursor of poly (imide-benzoxazole) (PIBO).

2. Description of the Related Arts

Presently, passivation material for semiconductor wafers is negative photosensitive polyimide, for which the ultimate resolution is 6 μm; however, this is not sufficient for the manufacture of semiconductors under 0.15 μm, for which the resolution must be at least 5 μm. In addition, organic solvents used as developers are environmentally unfriendly. Therefore, the development of positive alkali-soluble photoresists used as passivation films is of recent concern.

Passivation films of positive photosensitive polyimide have poor size-stability because of their high moisture uptake and are not applicable to future manufacturing of high-density semiconductor devices. The general properties of polybenzoxazole (PBO) are similar to polyimide (PI), but PBO has a lower moisture uptake and a lower dielectric coefficient than PI since the structure of PSO does not contain the polar carbonyl group (C═O) of PI. These unique properties of PBO enable it to pass the strict material requirements of the electronic industry. With excellent thermal stability, moisture resistance, and good electrical properties, in addition to the special molecular structure of its precursor, positive-workability, alkali-solubility, and heat-resistance, PBO can be applied to passivation of IC chips, dielectric layers, and wafer lever packaging (WLP). U.S. Pat. No. 5,449,584 to Sumitomo Bakelite discloses the application of PBO to wafer passivation films, but it has been found that PBO has poor adhesion to silicon wafers, thus causing peeling.

To improve the adhesion, PBO can be modified by the incorporation of PI to form a poly(imide-benzoxazole) (PIBO) copolymer. The synthesis of PIBO copolymer is disclosed in U.S. Pat. No. 5,985,969 to Dow Chemical, U.S. Pat. No. 5,071,948 to Hoechst Celanese, and a series of US patents to Toray. In these patents, PIBO copolymers are prepared through the condensation reaction of a pre-synthesized diamine monomer containing benzoxazole moiety with a dianhydride monomer. These synthetic methods involve complex monomer synthesis and purification procedures, both, however, tedious and expensive. It also should be noted that none of these patents disclose a PBO-PI copolymer containing hydroxyl (—OH) groups to improve adhesion to semiconductor substrates.

### SUMMARY OF THE INVENTION

It is therefore a primary object of the present invention to provide a positive photosensitive composition, comprising a poly(imide-benzoxazole) (PISO) precursor, a sensitizer, and a solvent. The precursor is a commercially available monomers and PIBO copolymer can be directly prepared by one-pot reaction without purification.

The second object of the present invention is to provide a method of pattern formation using the above mentioned positive photosensitive composition. The method comprises applying the positive photosensitive composition to a substrate, forming a pattern using lithography, and hard baking the substrate to cause dehydrative cyclization of the positive photosensitive composition to obtain a final pattern. The process is simpler than those using negative photosensitive polymers, and the resulting pattern has the advantages of thermal stability, high intensity, and excellent resolution. Therefore, the process can be applied to passivation films for semiconductor wafers.

### BRIEF DESCRIPTION OF THE DRAWINGS

The present invention will be more fully understood and further advantages will become apparent when reference is made to the following description of the invention and the accompanying drawings in which:

FIG. 1 represents the characteristic curve of poly(hydroxyamide-amic acid)/PIC-3 in the example of the present invention; X axis represents exposure dose (mJ/cm²), and Y axis represents normalized film thickness (μm).

FIG. 2 is a photograph showing the patterns formed by lithography using poly(hydroxyamide-amic acid)/PIC-3 in the example of the present invention.

### DETAILED DESCRIPTION OF THE INVENTION

Without intending to limit it in any manner, the present invention will be further illustrated by the following description.

The positive photosensitive composition of the present invention comprises a precursor of poly(imide-benzoxazole) copolymer as a base resin, a photosensitizer, and a solvent. Poly(imide-benzoxazole) copolymers are directly prepared from a trimellitic anhydride halide monomer and a bis(o-diaminophenol) monomer. A representative synthetic scheme is illustrated below:

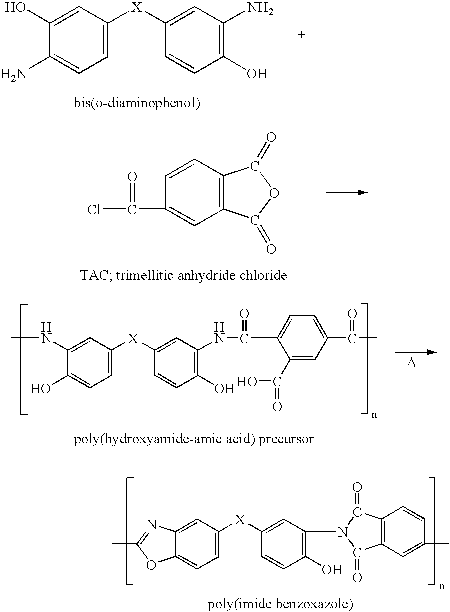

wherein X is —O—, —S—, —C(CF₃)₂—, —C(CH₃)₂—, —CO—, —CH₂—, —SO₂—, —SO—, or a bond; and n is an integer generally from about 10 to about 1000, preferably from about 20 to about 200.

The poly(hydroxyamide-amic acid) precursor is first synthesized by low-temperature solution polymerization in an organic solvent. Preferably, the bis(o-diaminophenol) monomer is dissolved in an organic solvent first and the trimellitic anhydride halide monomer then added to react with the bis(o-diaminophenol) monomer. It is found that a higher inherent viscosity can be obtained when the trimellitic anhydride halide is added in a solid state than in a liquid state. This may be due to the trimellitic anhydride halide reacting with the moisture in the solvent or the atmosphere. Suitable organic solvents include N-methyl pyrrolidone (NMP), pyridine, acetone, dimethyl formamide (DMF), and mixtures thereof. The reaction is preferably conducted under substantially anhydrous conditions from about 15° C. to −15° C., preferably from about 0° C. to −5° C. The most preferred trimellitic anhydride halide monomer is trimellitic anhydride chloride, and the most preferred bis(o-diaminophenol) monomer is 2,2-bis(3-amino-4-hydroxyphenol)hexafluoropropane (i.e., wherein X=—C(CF₃)₂—), both of which are commercially available.

In addition to trimellitic anhydride halide monomer and bis(o-diaminophenol), the polymer precursor may optionally be prepared using one or more other monomers, for example, a diacid dichloride such as terephthaloyl chloride or M-phthaloyl chloride. The optionally employed monomers may be added to the reaction mixture prior to or during the reaction of the trimellitic anhydride halide and bis(o-diaminophenol). A representative scheme including copolymerization of the diacid dichloride is as follows:

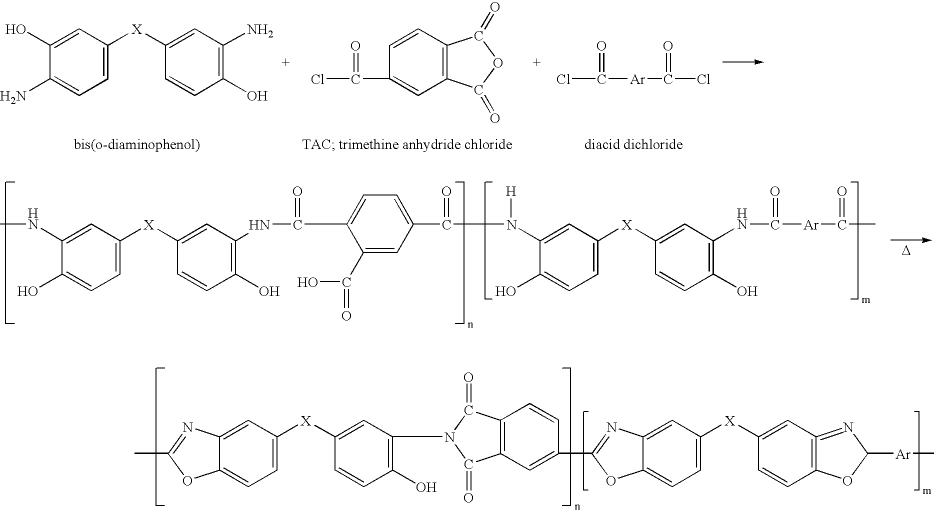

wherein

X and n are as set forth above,

Ar is

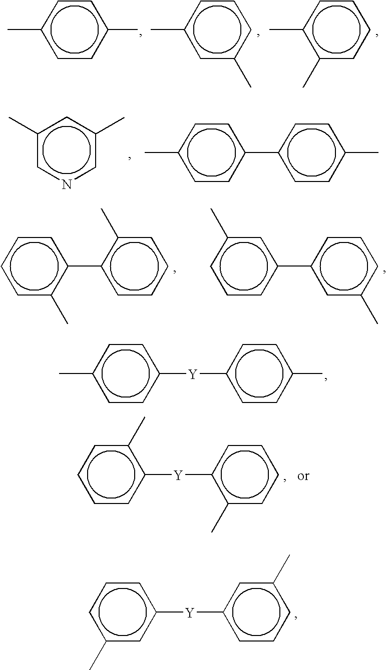

where Y is —O—, —S—, —C(CF₃)₂—, —C(CH₃)₂—, —CO—, —CH₂—, —SO₂—, or —SO—; and

m is an integer, and m+n is generally from about 10 to 100, preferably from about 20 to 200.

After the preparation of the poly(hydroxyamide-amic acid) precursor, the precursor, without subsequent purification, can be simply heated to a temperature sufficient to cause dehydrative cyclization to form the benzoxazole ring and the imide ring. The temperature can be from about 100° C. to 450° C., and preferably from about 300° C. to 400° C.

Of the positive photosensitive composition in the present invention, the poly(imide-benzoxazole) precursor is about 20 to 60% by weight, preferably about 10 to 40% by weight.

The photosensitive agents of the positive photosensitive composition in the present invention are diazonaphthoquinones as in the structures below:

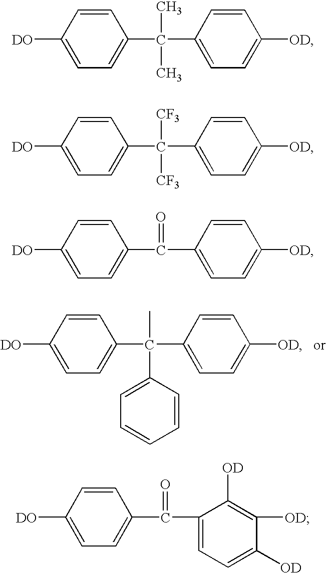

wherein D is hydrogen,

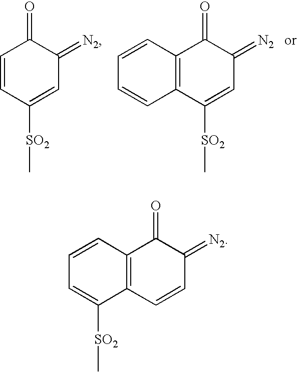

The photosensitive agent of the positive photosensitive composition is about 1 to 80% by weight, preferably about 10 to 40% by weight.

The solvent of the positive photosensitive composition includes N-methylpyrrolidinone, butyrolactone, N,N-dimethylamide, N,N-dimethyl formamide, or mixtures thereof, and is about 20 to 90% by weight, preferably about 40 to 80% by weight.

In another aspect of the present invention, a method of pattern formation is provided. The method comprises applying the positive photosensitive composition to a substrate to form a photoresist layer, performing lithography to the photoresist layer, wherein the lithography includes pre-baking the substrate with the photoresist layer thereon, exposing the substrate using a mask under a light source to obtain an exposure region, eliminating the exposure region by hydrophilic developer to obtain a pattern, and hard baking the substrate to cause dehydrative cyclization of the positive photosensitive composition to obtain a final pattern. The application step can use spin-coating at 2000 rpm with a thickness of the photoresist layer at 3 μm. The pre-baking step is performed at 105° C. for 4 minutes, and the hard baking step at 350° C. for 1 hour. In addition, the light source in the exposure step can comprise X-ray, electron beam, ultraviolet light, or visible light. Moreover, the hydrophilic developer can comprise alkali, primary amine, secondary amine, tertiary amine, aminoalcohol, quaternary amine salt or mixtures thereof. Pattern formation using the positive photosensitive composition of the present invention is simple and convenient. In addition, the final pattern has advantages of thermal stability, high intensity, and excellent resolution. Therefore, the pattern can be applied to passivation films for semiconductor wafers.

Preferred examples are illustrated below.

In all cases, the bis(3-amino-4-hydroxyphenol)hexafluoropropane (Bis-APAF) was purchased from Chriskkew; trimellitic anhydride chloride was purchased form Aldrich Chemical. Both were pre-dried at 60° C. for 24 hours. Anhydrous N-methylpyrrolidinone (NMP) and pyridine were purchased from Aldrich Chemical and can be used without pretreatment. 2,3,4-tris(1-oxo-2-diazonaphthoquinone-5-sulfonyloxy)-benzophenone (PIC-3) photosensitive compound was obtained from Koyo Chemicals (Japan),

### EXAMPLE 1

### Synthesis of Poly(hydroxyamide Amic Acid) Precursor

To a dry three-necked flask equipped with a nitrogen inlet and mechanical stirrer were added 7.83 g (21.4 mmol) of Bis-APAF, 3.63 g (35.9 mmol) of triethylamine, and 37.5 g of anhydrous NMP as a solvent. After the Bis-APAF was completely dissolved, the solution was cooled to −5° C. with ice and NaCl. 4.53 g (2.15 mmol) of trimellitic anhydride chloride was added slowly into the solution. After complete addition, the reaction mixture was stirred at room temperature for 16 hours. The resulting viscous solution was washed three times with pure water and once with a mixture of water and methanol (3:2). The precipitated polymer was collected by filtration and then dried in a vacuum oven at 60° C. for 24 hours. The polymer obtained is the poly(hydroxyamide-amic acid) precursor. The production rate is 98.9%, and IV=0.22dl/g.

### EXAMPLE 2

### Assays for the Positive Photosensitive Composition of the Present Invention

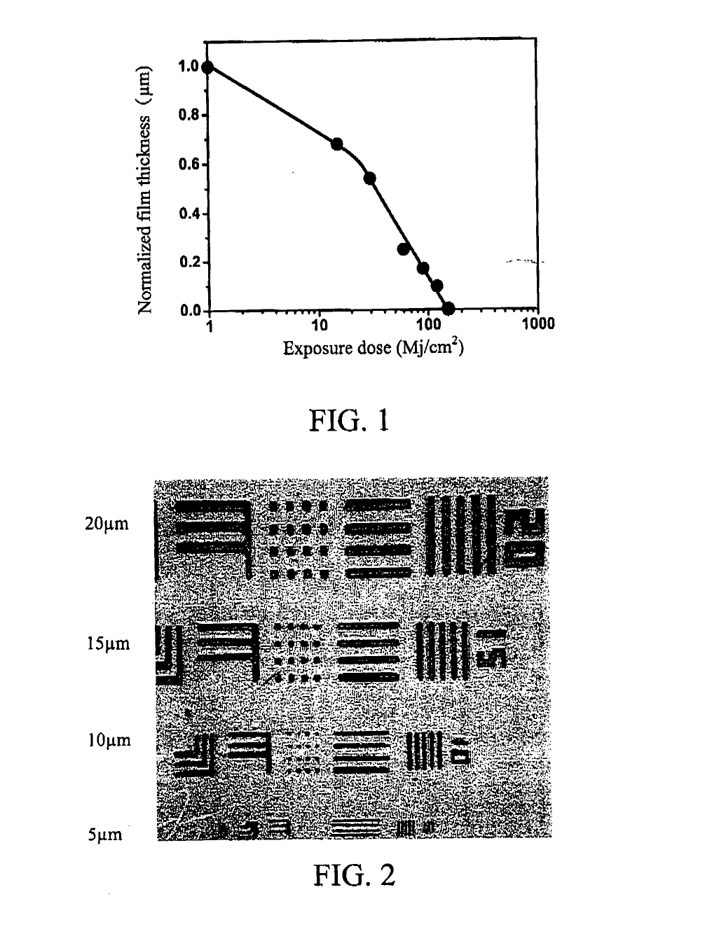

6 g of poly(hydroxyamide amic acid) precursor and 1.8 g of PIC-3 diazonaphthoquinone were dissolved in 20 g of gamma-butyrolactone (GBL) and the solution was passed through a 5 μm filter to provide a positive alkali-soluble photoresist solution with optical activities. The solution was spin-coated on a silicon chip. The chip was pre-baked at 105° C. for 4 minutes. At this stage, the thickness of the film measured by Tencoa-step spectrometer was 3 μm. The chip was exposed under a broadband (250-400 nm) light source, developed with 0.625% TMAH developer, and hard-baked at 350° C. for 1 hour. The results of normalized film thickness (μm) to exposure dose (mJ/cm²) are shown as a characteristic curve in FIG. 1. The sensitivity (exposure capacity) of the positive photosensitive composition in the present invention is 152 mJ/cm², and the contrast is 0.77. When the film thickness is 3 μm, the resolution can be up to 5 μm as shown in FIG. 2.

While the invention has been particularly shown and described with the reference to the preferred embodiments thereof, it will be understood by those skilled in the art that various changes in form and details may be made without departing from the spirit and scope of the invention.

What is claimed is:

1. A positive photosensitive composition, comprising:
a poly(imide-benzoxazole) precursor prepared by the reaction of trimellitic anhydride halide monomer with bis(o-diaminophenol) monomer, wherein the poly(imide-benzoxazole) comprises at least a repeating unit as the structure below: 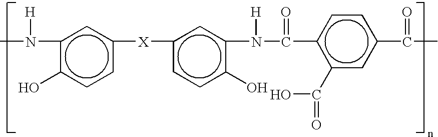
wherein the X is —O—, —S—, —C(CF₃)₂—, —C(CH₃)₂—, —CO—, —CH₂—, —NHCO—, —SO₂—, —SO—, or a bond; and
n is an integer from 10 to 100;
a photosensitizer; and
a solvent.

2. The positive photosensitive composition as claimed in claim 1, wherein the poly(imide-benzoxazole) precursor is prepared by the reaction of trimellitic anhydride chloride with bis(o-diaminophenol).

3. The positive photosensitive composition as claimed in claim 1, wherein the poly(imide-benzoxazole) precursor is prepared by the reaction of trimellitic anhydride chloride with 2,2-bis(3-amino-4-hydroxyphenol).

4. The positive photosensitive composition as claimed in claim 1, wherein X of the poly(imide-benzoxazole) precursor is —C(CF₃)₂—.

5. The positive photosensitive composition as claimed in claim 1, wherein the poly(imide-benzoxazole) precursor further comprises a repeating unit as the structure below: 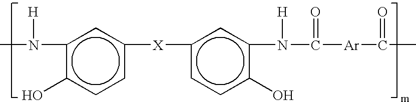
wherein X is as set forth in claim 1; Ar is 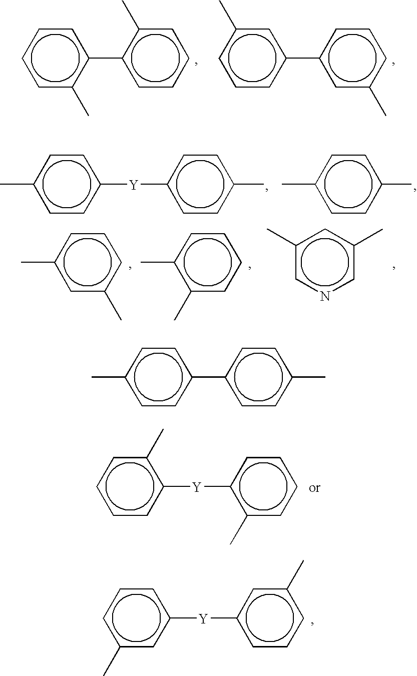
wherein Y is —O—, —S—, —C(CF)₂—, —C(CH₃)₂—, —CO—, —CH₂—, —SO₂—, or —SO—; and
m is an integer and m+n=10-100.

6. The positive photosensitive composition as claimed in claim 5, wherein the poly(imide-benzoxazole) precursor is prepared by the reaction of trimellitic anhydride chloride monomer, bis(o-diaminophenol) monomer, and terephthalate dichloride monomer.

7. The positive photosensitive composition as claimed in claim 5, wherein, of the poly(imide-benzoxazole) precursor, X is —C(CH₃)₂—, Ar is

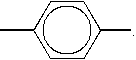

8. The positive photosensitive composition as claimed in claim 5, wherein, of the poly(imide-benzoxazole) precursor, X is —C(CH₃)₂—, Ar is

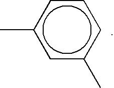

9. The positive photosensitive composition as claimed in claim 5, wherein, of the poly(imide-benzoxazole) precursor, m+n=10˜600.

10. The positive photosensitive composition as claimed in claim 1, wherein the poly(imide-benzoxazole) precursor is 20˜60% by weight.

11. The positive photosensitive composition as claimed in claim 10, wherein the poly(imide-benzoxazole) precursor is 10˜40% by weight.

12. The positive photosensitive composition as claimed in claim 1, wherein the photosensitizer comprises diazonaphthoquinones as the structures of 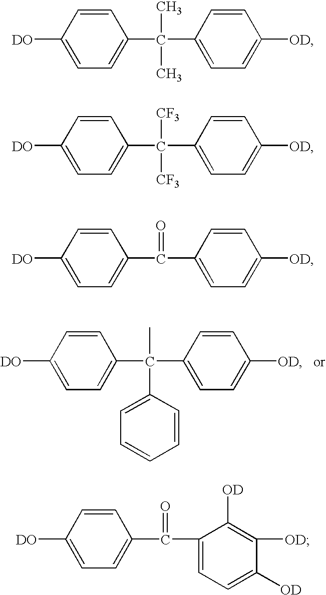
wherein D is hydrogen,

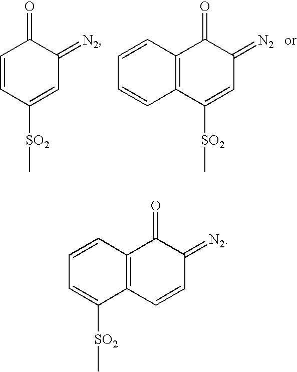

13. The positive photosensitive composition as claimed in claim 1, wherein the photosensitizer is about 1-80% by weight.

14. The positive photosensitive composition as claimed in claim 13, wherein the photosensitizer is about 10-40% by weight.

15. The positive photosensitive composition as claimed in claim 1, wherein the solvent comprises N-methylpyrrolidinone, butyrolactone, N,N-dimethylamide, N,N-dimethyl formamide, or mixtures thereof.

16. The positive photosensitive composition as claimed in claim 1, wherein the solvent is about 20-90% by weight.

17. The positive photosensitive composition as claimed in claim 16, wherein the solvent is about 40-80% by weight.

18. A method of pattern formation, comprising:
applying a positive photosensitive composition to form a photoresist layer;
performing lithography on the photoresist layer to obtain a pattern; and
hard baking the substrate to cause dehydrative cyclization of the positive photosensitive composition to obtain a final pattern;
wherein the positive photosensitive composition comprises:
a poly(imide-benzoxazole) precursor prepared by the reaction of trimellitic anhydride halide monomer with bis(o-diaminophenol) monomer, wherein the poly(imide-benzoxazole) precursor comprises at least a repeating unit as the structure below: 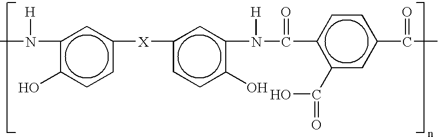
wherein the X is —O— —S—, —C(CF₃)₂—, —C(CH₃)₂—, —CO—, —CH₂—, —NHCO—, —SO₂—, —SO—, or a bond; and
n is an integer from about 10 to 100;
a photosensitizer; and
a solvent.

19. The method as claimed in claim 18, wherein the poly(imide-benzoxazole) precursor is prepared by the reaction of trimellitic anhydride chloride with bis(o-diaminophenol).

20. The method as claimed in claim 18, wherein the poly(imide-benzoxazole) precursor is prepared by the reaction of trimellitic anhydride chloride with 2,2-bis(3-amino-4-hydroxyphenol).

21. The method as claimed in claim 18, of the poly(imide-benzoxazole) precursor, wherein X is —C(CF₃)₂—.

22. The method as claimed in claim 18, wherein the poly(imide-benzoxazole) precursor further comprises a repeating unit as the structure below: 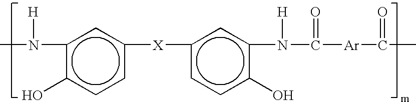
wherein X is as set forth in claim 1; Ar is 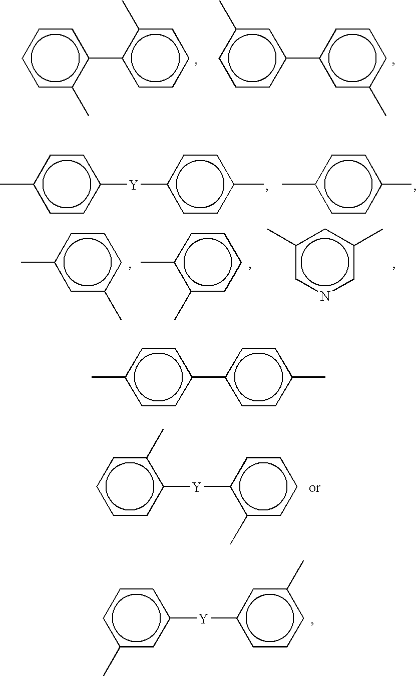
wherein Y is —O—, —S—, —C(CF₃)₂—, —C(CH₃)₂—, —CO—, —CH₂—, —SO₂—, or —SO—; and
m is an integer and m+n=10-100.

23. The method as claimed in claim 22, wherein the poly(imide-benzoxazole) precursor is prepared by the reaction of trimellitic anhydride chloride monomer, bis(o-diaminophenol) monomer, and diacid dichloride monomer.

24. The method as claimed in claim 22, wherein, of the poly(imide-benzoxazole) precursor, X is —C(CH₃)₂—, Ar is

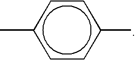

25. The method as claimed in claim 22, wherein, of the poly(imide-benzoxazole) precursor, X is —C(CH₃)₂—, Ar is

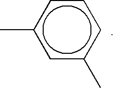

26. The method as claimed in claim 22, wherein, of the poly(imide-benzoxazole) precursor, m+n=10˜600.

27. The method as claimed in claim 18, wherein the poly(imide-benzoxazole) precursor is about 20˜60% by weight.

28. The method as claimed in claim 27, wherein the poly(imide-benzoxazole) precursor is about 10˜40% by weight.

29. The method as claimed in claim 18, wherein the photosensitizer comprises diazonaphthoquinones as the structures of 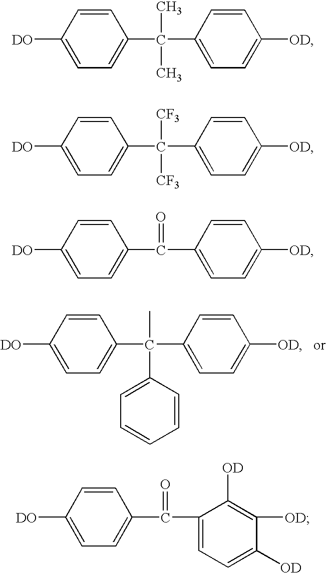
wherein D is hydrogen,

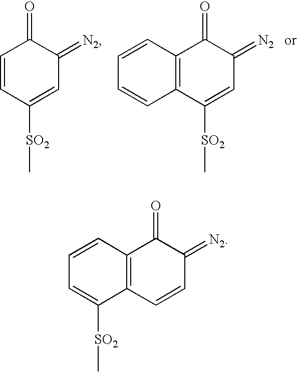

30. The method as claimed in claim 18, wherein the photosensitizer is about 1-80% by weight.

31. The method as claimed in claim 30, wherein the photosensitizer is about 10-40% by weight.

32. The method as claimed in claim 18, wherein the solvent comprises N-methylpyrrolidinone, butyrolactone, N,N-dimethylamide, N,N-dimethyl formamide, or mixtures thereof.

33. The method as claimed in claim 18, wherein the solvent is about 20-90% by weight.

34. The method as claimed in claim 33, wherein the solvent is about 40-80% by weight.

35. The method as claimed in claim 18, wherein the lithography comprises:
pre-baking the substrate with a photoresist layer thereon;
exposing the substrate uisng a mask under a light source to obtain a exposure region; and,
eliminating the exposure region by a hydrophilic developer to obtain a pattern.

36. The method as claimed in claim 35, wherein the light source is X-ray, electron beam, ultraviolet light, or visible light.

37. The method as claimed in claim 35, wherein the hydrophilic developer comprises alkali, primary amine, secondary amine, tertiary amine, aminoalcohol, quaternary amine salt, or mixtures thereof.
